(19) United States
(12) Patent Application Publication
(10) Pub. No.: US 2026/0140157 A1
(43) Pub. Date: May 21, 2026

(54) METHOD AND SYSTEM FOR ANALYSING AN EQUIPMENT FOR CURRENT CYCLING TEST

(71) Applicant: L&T TECHNOLOGY SERVICES LIMITED, Chennai, TN (US)

(72) Inventors: ABHAY DATTATRAYA WALIMBE, Mysore (IN); RACHANA KOMANDURI, Bangalore (IN); NIVEDITHA SURESHBABU, Bengaluru (IN)

(21) Appl. No.: 19/309,683

(22) Filed: Aug. 26, 2025

(30) Foreign Application Priority Data
Nov. 19, 2024 (IN) 202441089823

(51) Int. Cl. G01R 31/00

(52) U.S. Cl. CPC G01R 31/003

(57) ABSTRACT

A method and a system for analysing an equipment for current cycling test is disclosed. A processor receives an input dataset corresponding to the equipment. The input dataset includes a set of test control parameters, specification data, historical cycling test data and a set of setup parameters. The equipment is analysed based on the input dataset using an artificial intelligence (AI) model. The analysis is based on a validation of the specification data, the set of test control parameters and the set of test setup parameters with respect to the historical cycling test data. An outcome of the current cycling test is predicted based on the analysis as one of failure or pass. Upon predicting the outcome as failure, a reason of failure is determined by prompting a generative AI model.

### DESCRIPTION

### TECHNICAL FIELD

This disclosure relates generally to the field of analysing an equipment performance, and more specifically to a method and system for analysing an equipment for current cycling test.

### BACKGROUND

Current cycling tests are procedures used to evaluate the durability and performance of electrical components under continuous stress. These tests are conducted following industry standards like UL 486A and B, which require subjecting the equipment to a cycling process that takes 45 days to 90 days. The purpose of the current cycling tests is to ensure that the electrical components can withstand the difficulties of their intended operational environment. However, conventional current cycling tests are time-consuming, costly, and labour-intensive, which can significantly impact specified production timelines and overall resource efficiency.

One of the challenges faced by the conventional current cycling tests is the lengthy duration of these tests. Waiting up to 90 days to determine if an electrical component passes or fails is costly, especially when a failure occurs. The resources required to conduct the tests, including electricity, equipment, and manpower are substantial. Failures late in the process result in additional costs, project delays, and the need to repeat the tests which compounds the problem. Moreover, the physical infrastructure involved in the current cycling tests, such as cables and thermocouples experiences wear and tear which increases maintenance expenses and lowering overall testing efficiency.

Therefore, there is a need for a methodology for analysing an equipment for current cycling test, which can predict results of the current cycling test.

### SUMMARY OF THE INVENTION

In an embodiment, a method of analysing an equipment for current cycling test is disclosed. The method may include receiving, by a processor, an input dataset corresponding to the equipment. In an embodiment, the input dataset may include a set of test control parameters, specification data, historical cycling test data and a set of test setup parameters. The method may further include analysing, by the processor, the equipment based on the input dataset using an artificial intelligence (AI) model. In an embodiment, the analysis may be based on a validation of the specification data, the set of test control parameters and the set of test setup parameters with respect to the historical cycling test data. In an embodiment, the AI model may be trained to validate the specification data, the set of test control parameters and the set of test setup parameters based on the historical test data. The method may further include predicting, by the processor, an outcome of the current cycling test based on the analysis as one of failure or pass. The method may further include upon predicting the outcome as failure, determining, by the processor, a reason of failure by prompting a generative AI model. In an embodiment, the generative AI model may be prompted based on the specification data, the historical cycling test data and the set of test setup parameters.

In another embodiment, a system for analysing an equipment for current cycling test is disclosed. The system may include a processor, and a memory communicably coupled to the processor, wherein the memory stores processor-executable instructions, which when executed by the processor cause the processor to receive an input dataset corresponding to the equipment. In an embodiment, the input dataset may include a set of test control parameters, specification data, historical cycling test data and a set of test setup parameters. The processor may further analyse the equipment based on the input dataset using an artificial intelligence (AI) model. In an embodiment, the analysis may be based on a validation of the specification data, the set of test control parameters and the set of test setup parameters with respect to the historical cycling test data. In an embodiment, the AI model may be trained to validate the specification data, the set of test control parameters and the set of test setup parameters based on the historical cycling test data. The processor may further predict an outcome of the current cycling test based on the analysis as one of failure or pass. Upon predicting the outcome as failure, the processor may further determine a reason of failure by prompting a generative AI model. In an embodiment, the generative AI model may be prompted based on the specification data, the historical cycling test data and the set of test setup parameters.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this disclosure, illustrate exemplary embodiments and, together with the description, serve to explain the disclosed principles.

FIG. 1 is a block diagram of an exemplary system for analysing an equipment for current cycling test, in accordance with an embodiment of the present disclosure.

FIG. 2 is a schematic diagram of the computing device of the system of FIG. 1, in accordance with an embodiment of the present disclosure.

FIG. 3A illustrates an exemplary table depicting pre-processing of input data, in accordance with an embodiment of the present disclosure.

FIG. 3B illustrates another exemplary table depicting pre-processing of the input data, in accordance with an exemplary embodiment of the present disclosure.

FIG. 3C illustrates an exemplary graph depicting pre-processing of the input data, in accordance with an embodiment of the present disclosure.

FIG. 3D illustrates another exemplary table depicting pre-processing of the input data, in accordance with an embodiment of the present disclosure.

FIG. 4 illustrates an exemplary table depicting an outcome of the current cycling test, in accordance with an embodiment of the present disclosure.

FIG. 5A illustrates an exemplary text file of specification data, in accordance with an embodiment of the present disclosure.

FIG. 5B illustrates an exemplary table depicting historical cycling test data, in accordance with an embodiment of the present disclosure.

FIG. 6 is a flow diagram of a methodology of analysing an equipment for current cycling test, in accordance with an embodiment of present disclosure.

FIG. 7 is a flow diagram of a methodology of determining the input dataset corresponding to the equipment, in accordance with an embodiment of present disclosure.

### DETAILED DESCRIPTION OF THE DRAWINGS

Exemplary embodiments are described with reference to the accompanying drawings. Wherever convenient, the same reference numbers are used throughout the drawings to refer to the same or like parts. While examples and features of disclosed principles are described herein, modifications, adaptations, and other implementations are possible without departing from the scope of the disclosed embodiments. It is intended that the following detailed description be considered exemplary only, with the true scope being indicated by the following claims. Additional illustrative embodiments are listed.

Further, the phrases “in some embodiments”, “in accordance with some embodiments”, “in the embodiments shown”, “in other embodiments”, and the like mean a particular feature, structure, or characteristic following the phrase is included in at least one embodiment of the present disclosure and may be included in more than one embodiment. In addition, such phrases do not necessarily refer to the same embodiments or different embodiments. It is intended that the following detailed description be considered exemplary only, with the true scope being indicated by the following claims.

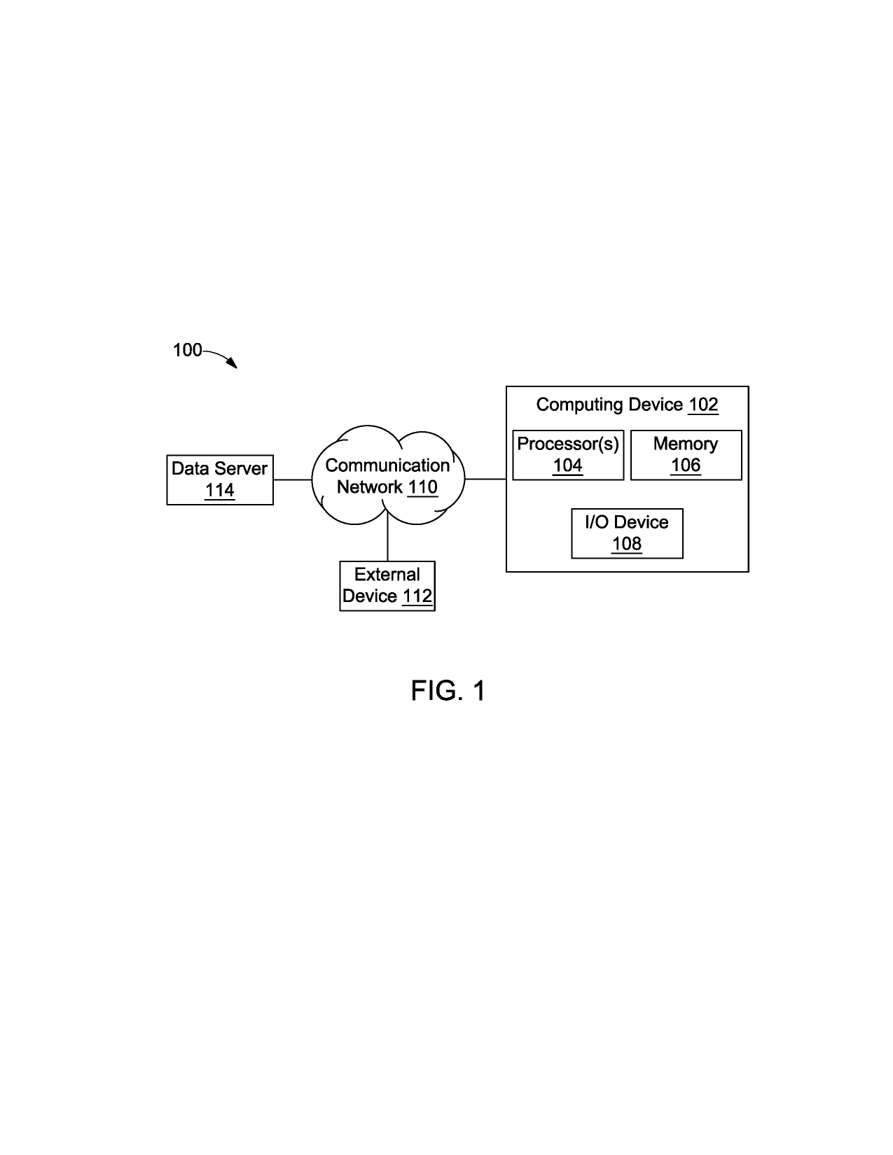

Referring now to FIG. 1, a block diagram of an exemplary system 100 for analysing an equipment for current cycling test, is illustrated, in accordance with an embodiment of the present disclosure. The system 100 may include a computing device 102, an external device 112, and a data server 114 communicably coupled to each other through a wired or wireless communication network 110. The computing device 102 may include a processor 104, a memory 106 and an input/output (I/O) device 108.

In an embodiment, examples of processor(s) 104 may include, but are not limited to, an Intel® Itanium® or Itanium 2 processor(s), or AMD® Opteron® or Athlon MP® processor(s), Motorola® lines of processors, Nvidia®, FortiSOC™, system on a chip processors or other future processors.

In an embodiment, the memory 106 may store instructions that, when executed by the processor 104, and cause the processor 104 to analyse the equipment for the current cycling test, as will be discussed in greater detail herein below. In an embodiment, the memory 106 may be a non- volatile memory or a volatile memory. In an embodiment, the memory 106 may also store a single module or a combination of different modules to analyse the equipment for the current cycling test. Examples of non-volatile memory may include but are not limited to, a flash memory, a Read Only Memory (ROM), a Programmable ROM (PROM), Erasable PROM (EPROM), and Electrically EPROM (EEPROM) memory. Further, examples of volatile memory may include but are not limited to, Dynamic Random Access Memory (DRAM), and Static Random-Access memory (SRAM).

In an embodiment, the I/O device 108 may comprise of variety of interface(s), for example, interfaces for data input and output devices, and the like. The I/O device 108 may facilitate inputting of instructions by a user communicating with the computing device 102. In an embodiment, the I/O device 108 may be wirelessly connected to the computing device 102 through wireless network interfaces such as Bluetooth®, infrared, or any other wireless radio communication known in the art. In an embodiment, the I/O device 108 may be connected to a communication pathway for one or more components of the computing device 102 to facilitate the transmission of inputted instructions and output results of data generated by various components such as, but not limited to, processor(s) 104 and memory 106.

In an embodiment, the data server 114 may be enabled in a remote cloud server or a co-located server and may include a database to store input data, input dataset, pre-processed data, forecasted data, outcome data and other data necessary for the system 100 such as, but not limited to historical cycling test data. In an embodiment, the data server 114 may store data input by an external device 112 (e.g., predefined pruning criterion, predefined pruning ratio) or output generated by the computing device 102. The data server 114 may also store a generative artificial intelligence (AI) model. The generative AI model stored within the data server 114 serves performs various computational tasks and applications. In an embodiment, the computing device 102 may be communicably coupled with the data server 114 through the communication network 110.

In an embodiment, the communication network 110 may be a wired or a wireless network or a combination thereof. The communication network 110 can be implemented as one of the different types of networks, such as but not limited to, ethernet IP network, intranet, local area network (LAN), wide area network (WAN), or a Metropolitan Area Network (MAN). Various devices in the system 100 may be configured to connect to the communication network 110, in accordance with various wired and wireless communication protocols. Examples of such wired and wireless communication protocols may include, but are not limited to, a Transmission Control Protocol and Internet Protocol (TCP/IP), User Datagram Protocol (UDP), Hypertext Transfer Protocol (HTTP), File Transfer Protocol (FTP), Zig Bee, EDGE, IEEE 802.11, light fidelity (Li-Fi), 802.16, IEEE 802.11s, IEEE 802.11g, multi-hop communication, wireless access point (AP), device to device communication, cellular communication protocols, and Bluetooth (BT) communication protocols. Further the communication network 110 can include a variety of network devices, including routers, bridges, servers, computing devices, storage devices, and the like.

In an embodiment, the computing device 102 may receive a plurality of inputs from the external device 112 through the communication network 110. In an embodiment, the computing device 102 and the external device 112 may be a computing system, including but not limited to, a laptop computer, a desktop computer, a notebook, a workstation, a server, a portable computer, a handheld or a mobile device. In an embodiment, the computing device 102 may be, but not limited to, in-built into the external device 112 or may be a standalone computing device.

In an embodiment, the computing device 102 may perform various processing in order to analyse an equipment for current cycling test. By way of an example, the computing device 102 may receive an input dataset corresponding to the equipment as an input. It should be noted that the input may be indicated or provided by a user via the I/O device 108. Examples of the equipment may include but not limited to, a neutral bar, a lug, and the like. The input dataset may include a set of test control parameters, specification data, historical cycling test data and a set of test setup parameters. In an embodiment, the historical cycling test data may include historical test data for a set of historical test setup parameters. In an embodiment, the specification data may include shape information, size information, type information, material information, and metallography parameters of the equipment. In an embodiment, the set of test control parameters may include an input current data, a cable type, a cable thickness, and voltage drop data. In an embodiment, the set of test setup parameters may include an ambient temperature. To determine the set of test setup parameters, the computing device 102 may determine an offset in at least one parameter of a set of preliminary test setup parameters and a set of historical test setup parameters using a machine learning (ML) model. The set of test setup parameters may be forecasted based on the offset using the ML model. Examples of ML model may include, but are not limited to, linear regression model, decision tree model, random forest model, etc.

To determine the input dataset, the computing device 102 may pre-process an input data. In order to pre-process the input data, the computing device 102 may remove missing values and outliers present in the input data. The computing device 102 may further categorize the input data based on a set of predefined categories. The computing device 102 may further normalize the input data based on a predefined normalizing value for each of the set of predefined categories.

The computing device 102 may further analyse the equipment based on the input dataset using an artificial intelligence (AI) model. In an embodiment, the analysis may be based on a validation of the specification data, the set of test control parameters and the set of test setup parameters with respect to the historical cycling test data. In an embodiment, the AI model may be trained to validate the specification data, the set of test control parameters and the set of test setup parameters based on the historical test data. Examples of the AI model may include but are not limited to, Convolutional Neural Network model, Recurrent Neural Network, Autoencoders, Random Forest Model, transformer-based models, etc.

The computing device 102 may further predict an outcome of the current cycling test based on the analysis as one of failure or pass. Upon predicting the outcome as failure, the computing device 102 may further determine a reason of failure by prompting a generative AI model. The generative AI model may be prompted based on the specification data, the historical cycling test data and the set of test setup parameters. Examples of generative AI model may include but are not limited to, ChatGPT, BERT, T5, XLNet, RoBERTa, etc.

Upon predicting the outcome as pass, the computing device 102 may label the set of test control parameters based on the outcome to determine labelled data. Furthermore, the computing device 102 may store the labelled data in the database. The computing device 102 may further fine-tune the AI model based on the labelled data and/or the reason of failure of the equipment.

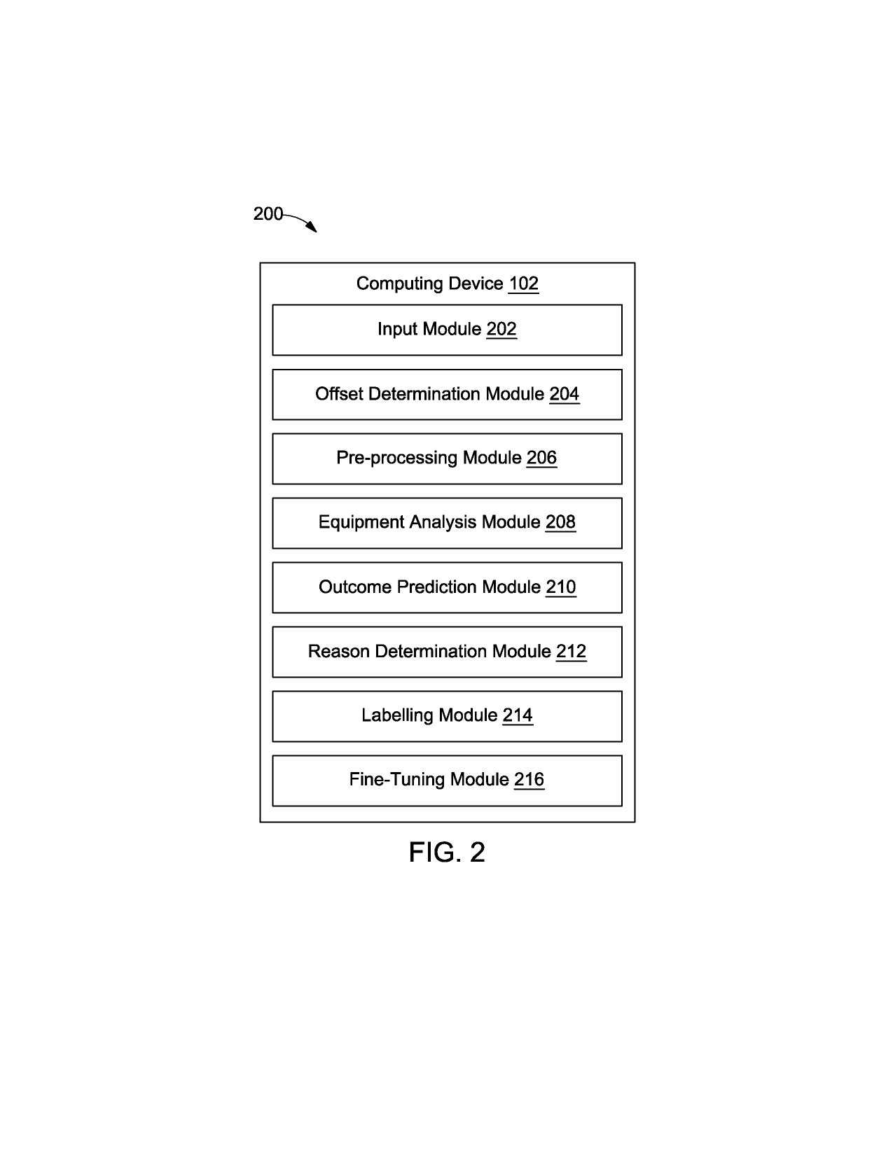

Referring now to FIG. 2, a schematic diagram 200 of the computing device 102 of the exemplary system of FIG. 1, in accordance with an embodiment of the present disclosure. In an embodiment, the computing device 102 may include an input module 202, an offset determination module 204, a pre-processing module 206, an equipment analysis module 208, an outcome prediction module 210, a reason determination module 212, a labelling module 214, and a fine-tuning module 216.

The input module 202 may receive an input dataset corresponding to the equipment as an input. It should be noted that the input may be indicated or provided by a user via the I/O device 108. Examples of the equipment may include but not limited to, neutral bars, lugs, power cables, electric motors, transformers, and other electrical components. Neutral bars and lugs are typically used in electrical distribution panels and equipment, where their performance under electrical load cycling is critical. The input dataset corresponding to the equipment provides essential parameters that allow the computing device 102 to perform validation, prediction, and fault detection during the current cycling tests. The input dataset may include a set of control parameters, specification data, historical cycling test data and a set of test setup parameters.

In an embodiment, the set of test control parameters may include variables that define the operational settings of the current cycling test, such as, but not limited to, an input current data, a cable type, a cable thickness, and voltage drop data. For example, when testing a neutral bar, the set of control parameters might specify the input current of 100 amps, the specific type of cable (such as copper or aluminium), and the cable thickness (e.g., 10 mm), alongside the expected voltage drop during the current cycling test. In an embodiment, the specification data may be detailed information about the equipment itself and may be critical for comparison and validation purposes. For instance, the specification data may include shape information such as whether a lug is flat, circular, or angled. The specification data may also include size information such as the length and width of a neutral bar. The specification data may also include type information such as whether the equipment is a high-voltage power cable or a low-voltage neutral bar. The specification data may also include material information such as copper for cables or aluminium alloys for lugs. The specification data may also include metallography parameters of the equipment including grain size, phase distribution, and inclusion content, which are critical for assessing mechanical and electrical performance of the equipment under repeated cycling of the current cycling test.

In an embodiment, the historical cycling test data may include historical test data for a set of historical test setup parameters. The historical test data may include data from previous tests performed on similar equipment under varying conditions. For example, in the case of testing a transformer, the historical test data might consist of historical current cycling tests conducted at different load levels and environmental conditions. The historical test data may include the failure points, operating temperatures, voltage ratings, and specific performance metrics from past tests.

In an embodiment, the set of test setup parameters may include an ambient temperature. The set of test setup parameters define the environmental and operational context in which the current cycling test is conducted. For example, the setup parameters may include ambient temperature, humidity levels, or other environmental conditions that could influence the performance of the equipment. For example, in testing a power cable, an ambient temperature of 40°C could be part of the test setup parameters, as the ambient temperature directly impacts the thermal behaviour and resistance of the cable under load.

To determine the set of test setup parameters, the offset determination module 204 may determine an offset in at least one parameter of a set of preliminary test setup parameters and a set of historical test setup parameters using a machine learning (ML) model. The set of test setup parameters may be forecasted based on the offset using the ML model. Examples of ML model may include, but are not limited to, linear regression model, decision tree model, random forest model, etc.

In an exemplary embodiment, to determine the set of test setup parameters, the offset determination module 204 determines any deviations or differences (referred to as "offsets") between the set of preliminary test setup parameters and the set of historical test setup parameters. The offset determination module 204 uses a machine learning (ML) model that has been trained to recognize patterns and trends in the set of historical test setup parameters. Once the offset is determined, the ML model forecasts the set of test setup parameters, which will be used for analysing the equipment for the current cycling test. In an embodiment, the set of preliminary test setup parameters may refer to the parameters determined from conducting the current cycling test on the equipment for a first few cycles of the current cycling test. The offset determination module 204 compares the set of preliminary test setup parameters with the set of historical test setup parameters.

To determine the input dataset, the pre-processing module 206 may pre-process an input data. In an embodiment, the pre-processing module 206 may receive raw data from various sources, such as equipment logs, user inputs, or external databases. This input data may include inconsistencies, missing fields, or values that significantly deviate from expected norms, which can negatively affect the results of the analysis if not handled properly.

In order to pre-process the input data, the pre-processing module 206 may remove missing values and outliers present in the input data. In an exemplary embodiment, the pre-processing module 206 cleans the input data by identifying and handling missing values. Missing values in the data may arise due to various reasons such as sensor malfunctions, incomplete data logging, or communication errors. For example, in the case of a current cycling test for a power cable, the test might have missing data points for the cable’s resistance at specific time intervals. The pre-processing module 206 module may remove these missing values. In addition to handling missing values, the pre-processing module 206 also identifies and removes outliers’ data points that significantly deviate from the typical range. For example, in testing a battery pack, if the recorded voltage during a cycling test shows a sudden spike that exceeds the normal operating range, it could indicate an anomaly in the data collection process rather than a legitimate performance characteristic of the battery. The pre-processing module 206 uses statistical techniques to detect and filter out such outliers to ensure that the input dataset is consistent and reliable for further analysis.

The pre-processing module 206 may further categorize the input data based on a set of predefined categories. In an exemplary embodiment, once the input data is cleaned, the pre-processing module 206 organizes the input data into a set of predefined categories. For example, when analyzing equipment like neutral bars or lugs, the input data may include parameters such as material type, electrical conductivity, or physical dimensions. Here, the categorization might separate electrical parameters (e.g., voltage, current) from physical specifications (e.g., core size, winding material) and environmental conditions (e.g., ambient temperature, humidity).

The pre-processing module 206 may further normalize the input data based on a predefined normalizing value for each of the set of predefined categories. In an exemplary embodiment, after categorization, the pre-processing module 206 normalizes the input data to ensure that the input data is on a comparable scale. Normalization is crucial because the parameters in the input data may have different units of measurement and ranges, which may skew the analysis if not properly aligned.

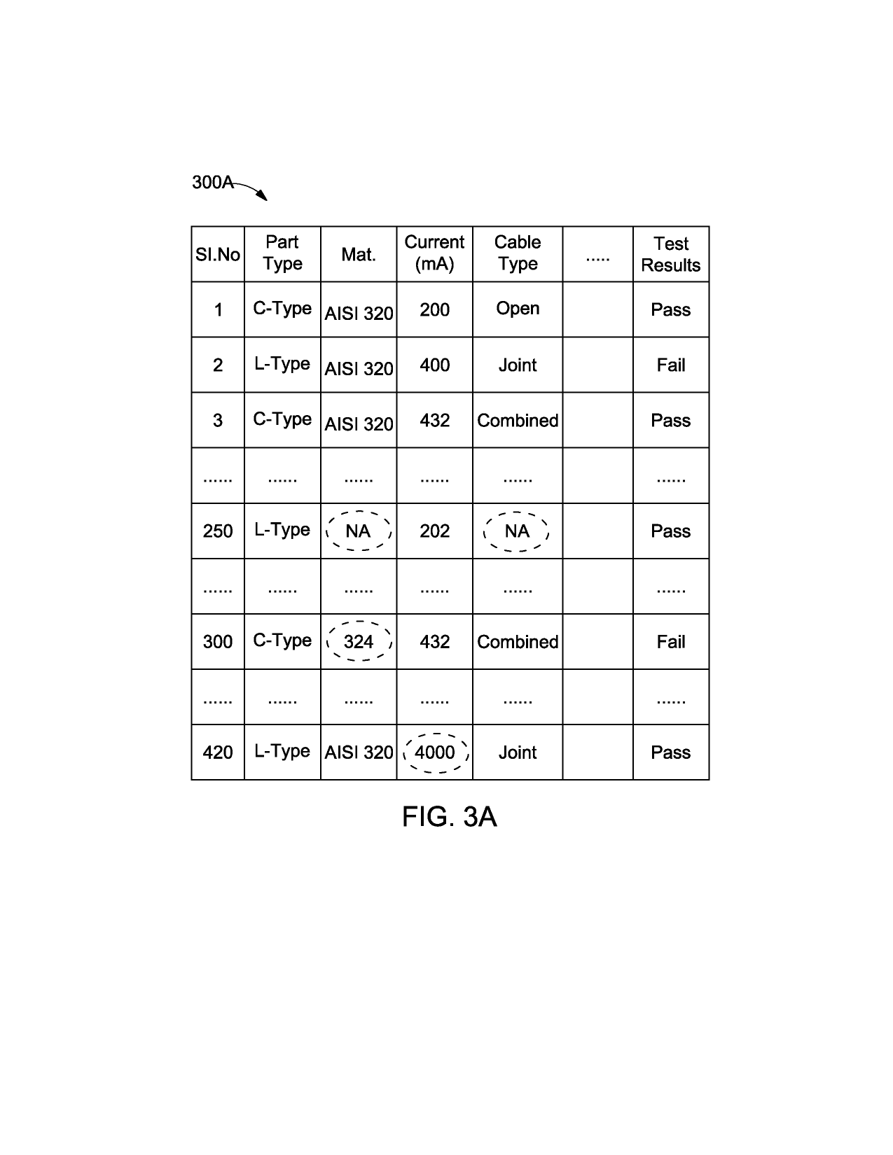

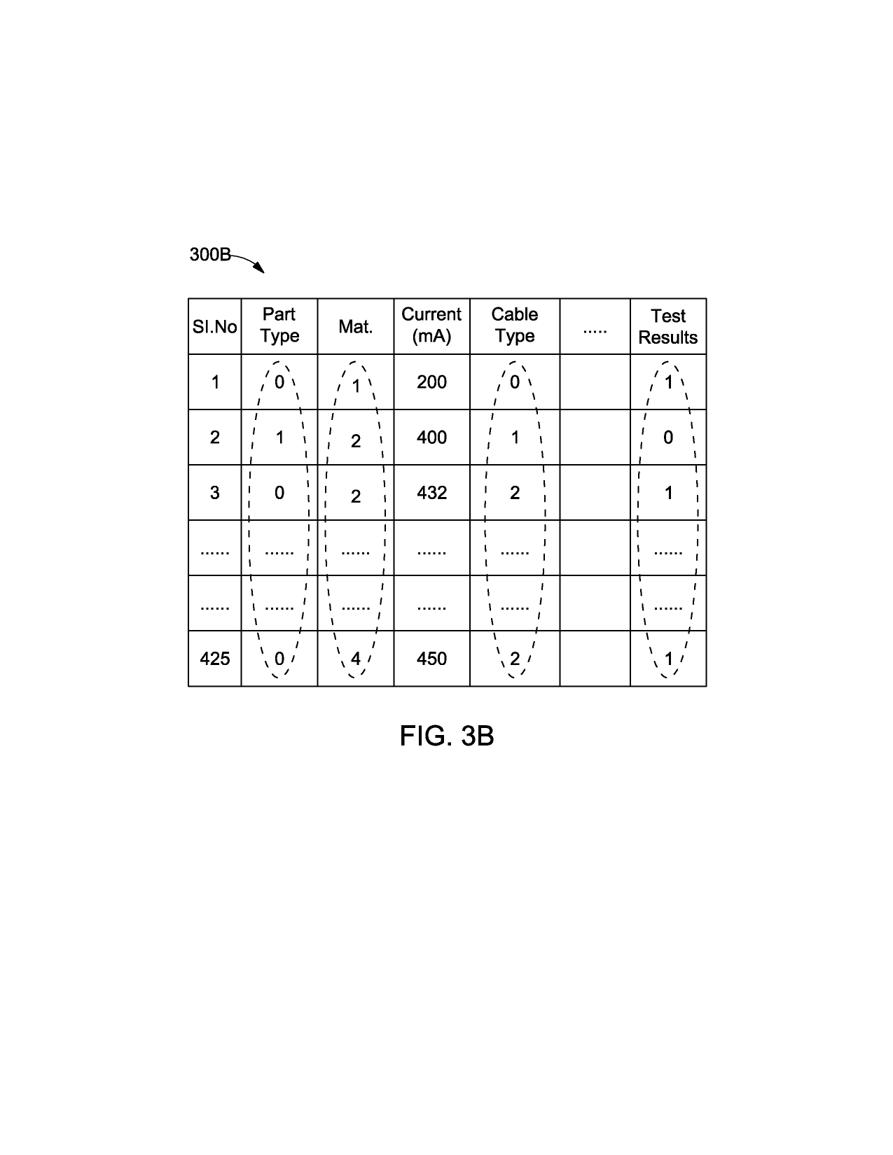

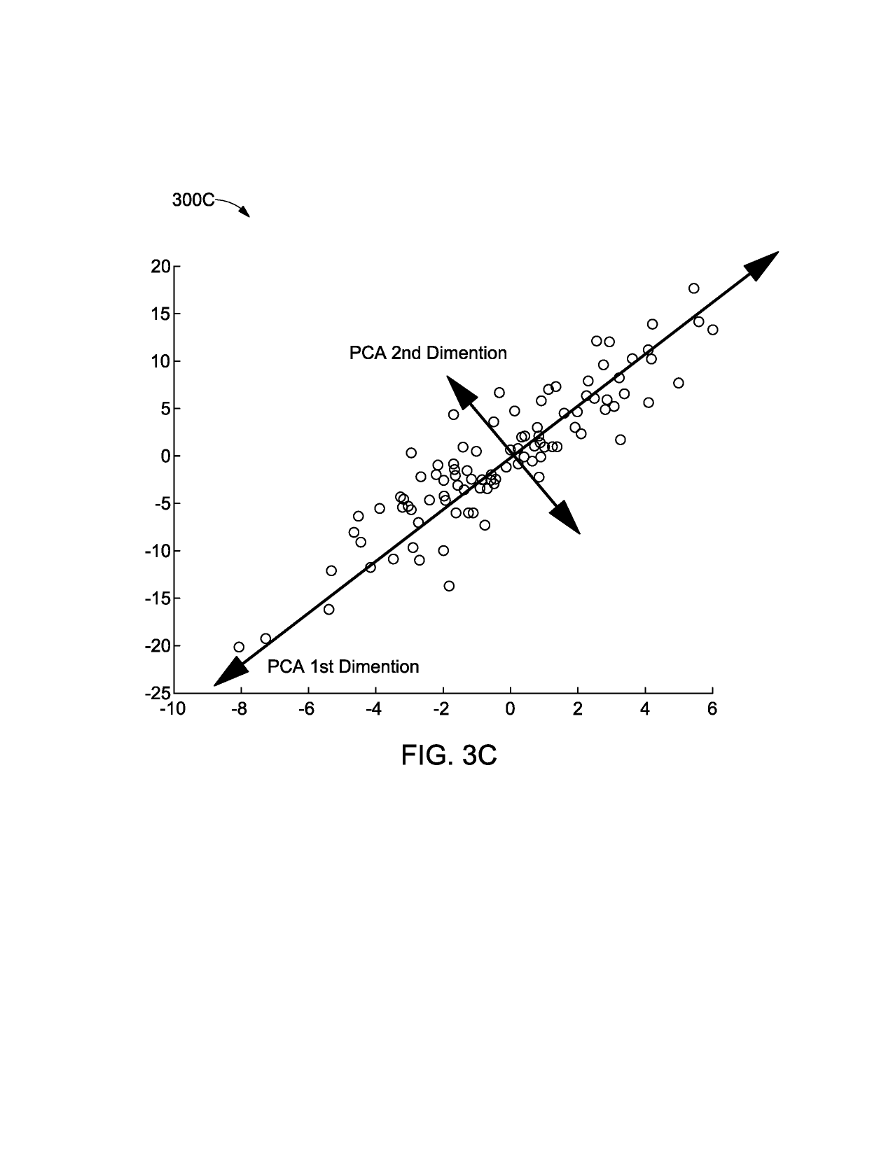

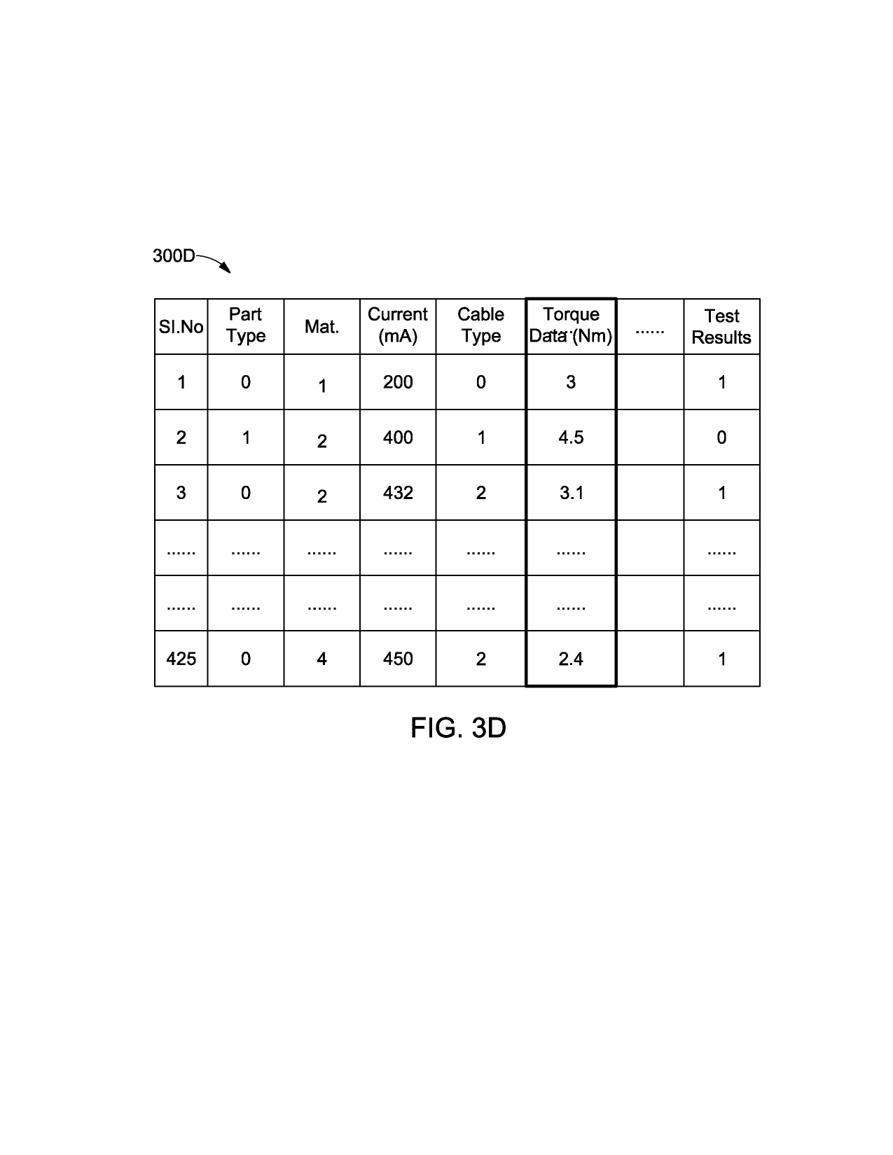

Referring now to FIG. 3A, an exemplary table 300A depicting pre-processing of input data, is illustrated, in accordance with an embodiment of the present disclosure. In this embodiment, the pre-processing module 206 pre-process the input data by removing any missing values and identifying outliers that could affect the integrity of the analysis. The table 300A depicts examples where missing or abnormal data points are flagged, which are then handled by the pre-processing module 206.

In this table 300A, row with serial number 250 demonstrate an instance where certain data points are missing. Specifically, the material column shows "NA" (Not Applicable), and the cable type is also marked as "NA," indicating that the relevant data for this test setup was not provided or recorded. The pre-processing module 206 may identify such missing values and remove these missing values. Another example is seen in rows with serial number 300 and 420 where certain values stand out as potential outliers. In row with serial number 300, the material column shows 324 mA, which deviates from the category for this test setup. Similarly, in row with serial number 420, the current is recorded as 4000 mA, an unusually high value compared to the other test entries in the table 300A. These values are flagged as outliers, as they may distort the analysis or results. The pre-processing module 206 may identify these outliers using statistical methods, and take corrective actions, such as removing the outliers or adjusting the dataset accordingly.

Referring now to FIG. 3B, another exemplary table 300B depicting pre-processing of the input data, is illustrated, in accordance with an exemplary embodiment of the present disclosure. The table 300B depicts how the pre-processing module 206 categorizes and encodes the input data into numerical values to ensure that the input data is standardized for analysis by machine learning models.

The input data in FIG. 3B has been categorized based on a set of predefined categories such as Part Type, Material, Cable Type, and Test Results. Each category is assigned a unique numeric value for ease of processing. These encoded values are particularly useful for machine learning algorithms that require numerical input to function effectively. For instance, in case of part type, categorical values such as “C-type” and “L-type” are assigned numerical codes such as “0” represents “C-type” and “1” represents “L-type”. In case of material types, different material types are also encoded as “1” represents “AISI 320”, “2” represents another material, and like. In case of cable type, various configurations of cables are assigned numeric codes such as “0” represents “Open”, “1” represents “Joint”, and “2” represents “Combined”. In case of test results, the test results also be encoded such as “1” indicates “Pass” and “0” indicates “Fail”.

Referring now to FIG. 3C, an exemplary graph 300C depicting pre-processing of the input data, is illustrated, in accordance with an embodiment of the present disclosure. The graph 300C depicts how the pre-processing module 206 reduces dimensionality of the input data using a technique like Principal Component Analysis (PCA). Dimensionality reduction simplifies the complexity of the input data while retaining its significant features for analysis.

In FIG. 3C, the input data, which may originally exist in a high-dimensional space, is projected onto two principal components, PCA 1^{st} Dimension (Principal Component 1) and PCA 2nd Dimension (Principal Component 2). The principal component 1 and the principal component 2 represent the directions of maximum variance in the input data. The arrows in the graph 300C indicate the new axis, or principal components, onto which the data points (represented by small circles) are projected. This results in a reduced two-dimensional representation of the input data.

It is to be noted that, PCA is a technique for reducing the number of variables in large datasets while preserving the variance and important structure within the data. In this embodiment, the pre-processing module 206 performs PCA to extract key features from the input data and projects the input data onto a lower-dimensional space. This allows the computing device 102 to process large datasets more efficiently by focusing on the most informative aspects of the input data. The PCA 1^{st} Dimension captures the direction of maximum variance, meaning the PCA 1^{st} Dimension represents the most important feature in the input data. The PCA 2^{nd} Dimension is orthogonal to the PCA 1^{st} Dimension and captures the second most significant direction of variance to add additional useful information.

Referring now to FIG. 3D, another exemplary table 300D depicting pre-processing of the input data, is illustrated, in accordance with an embodiment of the present disclosure. The table 300D depicts how the pre-processing module 206 eliminate redundant or less significant features from the input data by using recursive feature elimination (RFE).

It is to be noted that, RFE is a feature selection technique that recursively removes the least important features from the dataset. RFE works by building a model, evaluating its performance, and the eliminating the least significant feature until the desired number of features is reached. In FIG. 3D, the input data initially includes multiple features such as part type, material type, current, cable type, torque data, test results. The process begins with the initial model (i.e., input data) containing all the variables. In this particular table 300D, Torque Data (Nm) is identified as a redundant feature and is removed from the final model (i.e., input dataset). The final model (i.e., input dataset) retains only the most relevant features, such as part type, material type, current, and cable type, which are important for predicting the cycling test results.

Referring back to FIG. 2, the equipment analysis module 208 may analyse the equipment based on the input dataset using an artificial intelligence (AI) model. In an embodiment, the analysis may be based on a validation of the specification data, the set of test control parameters and the set of test setup parameters with respect to the historical cycling test data. In an embodiment, the AI model may be trained to validate the specification data, the set of test control parameters and the set of test setup parameters based on the historical test data. For example, the AI model compares the current equipment specification data (such as shape, size, material, and metallography parameters) against the historical test data to ensure that the equipment matches the required standards for testing. The AI model also validates the set of test control parameters (e.g., input current, cable type, cable thickness, voltage drop) and the set of test setup parameters (e.g., ambient temperature) with historical test data to determine whether the equipment is set up for optimal testing conditions. Examples of the AI model may include but are not limited to, Convolutional Neural Network model, Recurrent Neural Network, Autoencoders, Random Forest Model, transformer-based models, etc.

In an exemplary scenario, consider an electrical connector made from a material like AISI 320 steel undergoing a current cycling test. The equipment analysis module 208 takes as input the material specifications, including the size and shape of the connector, the set of test control parameters including the input current set for the test, and the set of test setup parameters including ambient temperature. The AI model checks these parameters against the historical test data where similar connectors were tested. If, for example, the historical test data reveals that connectors of similar size and material failed under certain temperatures or current levels, the AI model might predict a higher failure risk for the current test.

In an embodiment, there may be more than one artificial intelligence (AI) model to analyse the equipment based on the input dataset. The equipment analysis module 208 may employ a set of AI models, which may include models such as logistic regression, support vector machines (SVM), random forests, deep neural networks, and transformer-based classification models (e.g., Generative AI models). Each AI model may specialize in a specific aspect of the analysis, such as validating the equipment specification data, the set of test control parameters, and the set of test setup parameters. For example, the AI models may operate in an ensemble fashion, where the input dataset is divided into subsets, and each subset is analysed by a specific AI model to provide a multi-faceted analysis.

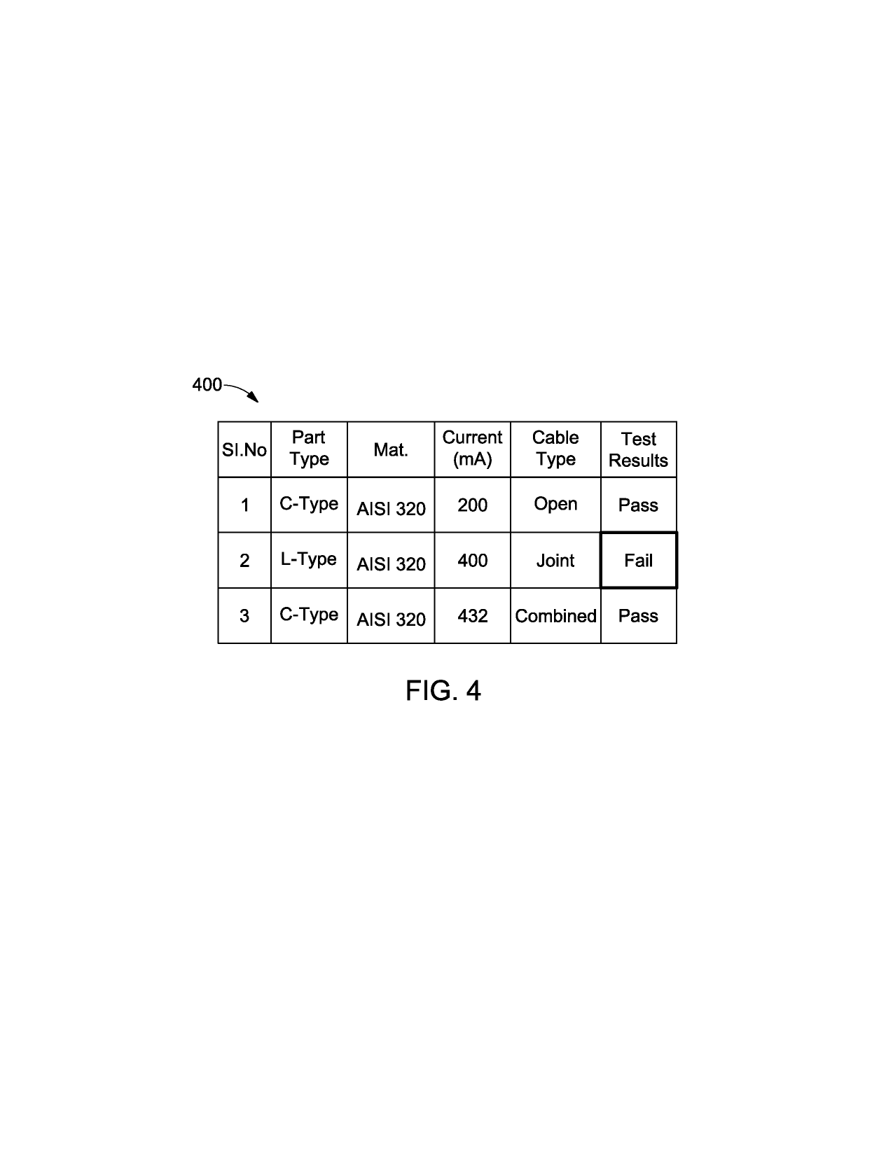

Further, the outcome prediction module 210 may predict an outcome of the current cycling test based on the analysis as one of failure or pass. The outcome prediction module 210 uses the results from the analysis to forecast whether the equipment will pass or fail the current cycling test. Referring now to FIG. 4, an exemplary table 400 depicting an outcome of the current cycling test, is illustrated, in accordance with an embodiment of the present disclosure. The table 400 depicts the results of cycling tests performed on different equipment parts, where the outcome is classified as either "Pass" or "Fail" based on the success or failure of the current cycling test.

The table 400 includes a plurality of columns, each representing specific details about the equipment being tested, along with the outcome (i.e., result) of the current cycling test. The plurality of columns may include, but not limited to, a serial number column, a part type column, a material column, a current column, a cable type column, a test result column. The first test may be conducted on a “C-type part” made from “AISI 320 material”, subjected to a current of “200 mA” with an “Open cable type”. The test resulted in a “Pass”, which indicates the equipment successfully endured the test conditions. The second test involved an L-type part, also made from “AISI 320” material, but subjected to a higher current of “400 mA” with a “Joint cable type”. This test resulted in a “Fail” which imply that the equipment may be unable to withstand the applied current and test conditions which may lead to a failure of the equipment. The third test may be carried out on another “C-type part”, made from “AISI 320” material, subjected to “432 mA” of current using a “Combined cable type”. The test resulted in a “Pass” which shows that the equipment successfully endured the test conditions.

Referring back to FIG. 2, upon predicting the outcome as failure, the reason determination module 212 may further determine a reason of failure by prompting a generative AI model. The generative AI model may be prompted based on the specification data, the historical cycling test data and the set of test setup parameters. Examples of generative AI model may include but are not limited to, ChatGPT, BERT, T5, XLNet, RoBERTa, etc. Consider an example where a C-type equipment made from AISI 320 material fails the current cycling test under a current load of 450 mA with a Combined cable type. Upon failure detection, the generative AI model is prompted and analyses the specification data and the historical cycling test data. In this case, the generative AI model identifies that a similar failure occurred in a previous test due to an overcurrent condition exceeding the tolerance of material, which led to overheating of the equipment. The generative AI model may also determine that the test setup parameters specifically the cable type may not be optimized for the given current which results in excess resistance and a failure in current flow. By correlating this with the past failures where the combined cable type may be used under high current, the generative AI model may suggest that using a different cable type, such as an Open configuration, may prevent this issue in the future.

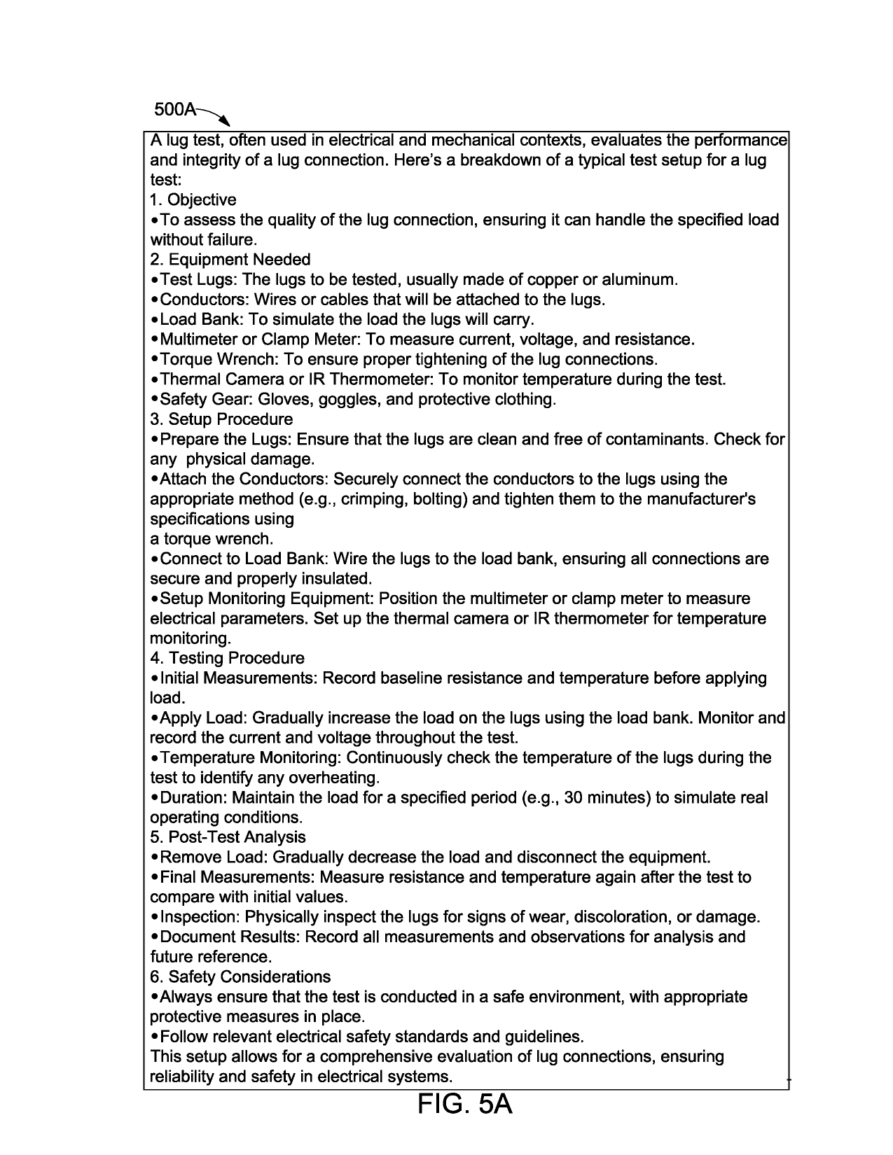

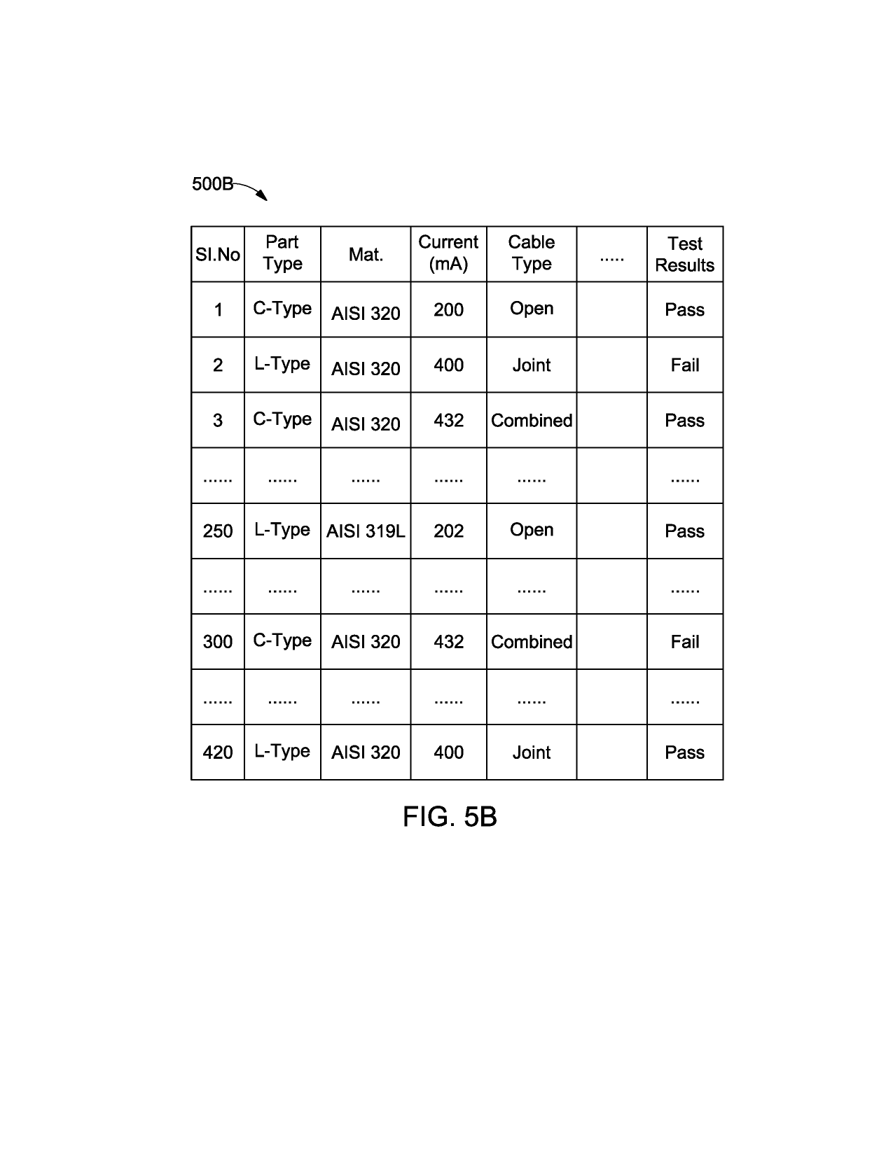

Referring now to FIG. 5A, an exemplary text file 500A of the specification data, is illustrated, in accordance with an embodiment of the present disclosure. FIG. 5A provides a detailed breakdown of the specification data required for conducting a current cycling test on a lug, which is used to evaluate the performance and integrity of lug connections in electrical and mechanical systems. The text file 500A in FIG. 5A outlines the various elements involved in the lug testing process. The specification data covers multiple categories that may include, but not limited to, objective, equipment needed, setup procedure, testing procedure, post-test analysis, and safety considerations. In an embodiment, the specification data in FIG. 5A may vary based on the equipment being tested, the environmental conditions of the test, and specific industrial standards.

Referring now to FIG. 5B, an exemplary table 500B depicting the historical cycling test data, is illustrated, in accordance with an embodiment of the present disclosure. The table 500B may include a plurality of columns, each representing specific attributed related to the historical cycling test data of the current cycling test performed on the lug. The historical cycling test data may be used to analyse trends, detect failure patterns, and validate current test results. The historical cycling test data may be an input for the AI model to predict the performance of lug connections in current tests. The historical cycling test data may also be an input for the generative AI model to determine the reason of failure if the lug fails the current cycling test.

Referring back to FIG. 2, Upon predicting the outcome as pass, the labelling module 214 may label the set of test control parameters based on the outcome to determine labelled data. This labelling process ensures that each set of parameters associated with successful test outcomes is accurately categorized for training of the AI model. In an embodiment, the labelling module 214 may operate if a set of test control parameters (such as current, cable type, and material type) leads to a pass result during a current cycling test, the labelling module 214 labels this specific configuration as "pass". The labelled data may include detailed information about the test parameters, such as the type of lug, material used, current applied, and cable configuration. This ensures that the labelling module 214 retains a comprehensive record of conditions under which the equipment passed the test. Furthermore, the labelling data 214 may store the labelled data in the database. Further, the fine-tuning module 216 may fine-tune the AI model based on the labelled data and/or the reason of failure of the equipment.

It should be noted that all such aforementioned modules 202-216 may be represented as a single module or a combination of different modules. Further, as will be appreciated by those skilled in the art, each of the modules 202-216 may reside, in whole or in parts, on one device or multiple devices in communication with each other. In some embodiments, each of the modules 202-216 may be implemented as dedicated hardware circuit comprising custom application-specific integrated circuit (ASIC) or gate arrays, off-the-shelf semiconductors such as logic chips, transistors, or other discrete components. Each of the modules 202-216 may also be implemented in a programmable hardware device such as a field programmable gate array (FGPA), programmable array logic, programmable logic device, and so forth. Alternatively, each of the modules 202-216 may be implemented in software for execution by various types of processors (e.g. processor 104). An identified module of executable code may, for instance, include one or more physical or logical blocks of computer instructions, which may, for instance, be organized as an object, procedure, function, or other construct. Nevertheless, the executables of an identified module or component need not be physically located together but may include disparate instructions stored in different locations which, when joined logically together, include the module and achieve the stated purpose of the module. Indeed, a module of executable code could be a single instruction, or many instructions, and may even be distributed over several different code segments, among different applications, and across several memory devices.

As will be appreciated by one skilled in the art, a variety of processes may be employed for analysing an equipment for current cycling test. For example, the exemplary system 100 and the associated computing device 102 may analyse an equipment for current cycling test by the processes discussed herein. In particular, as will be appreciated by those of ordinary skill in the art, control logic and/or automated routines for performing the techniques and steps described herein may be implemented by the system 100 and the associated computing device 102 either by hardware, software, or combinations of hardware and software. For example, suitable code may be accessed and executed by the one or more processors on the system 100 to perform some or all of the techniques described herein. Similarly, application specific integrated circuits (ASICs) configured to perform some, or all of the processes described herein may be included in the one or more processors on the system 100.

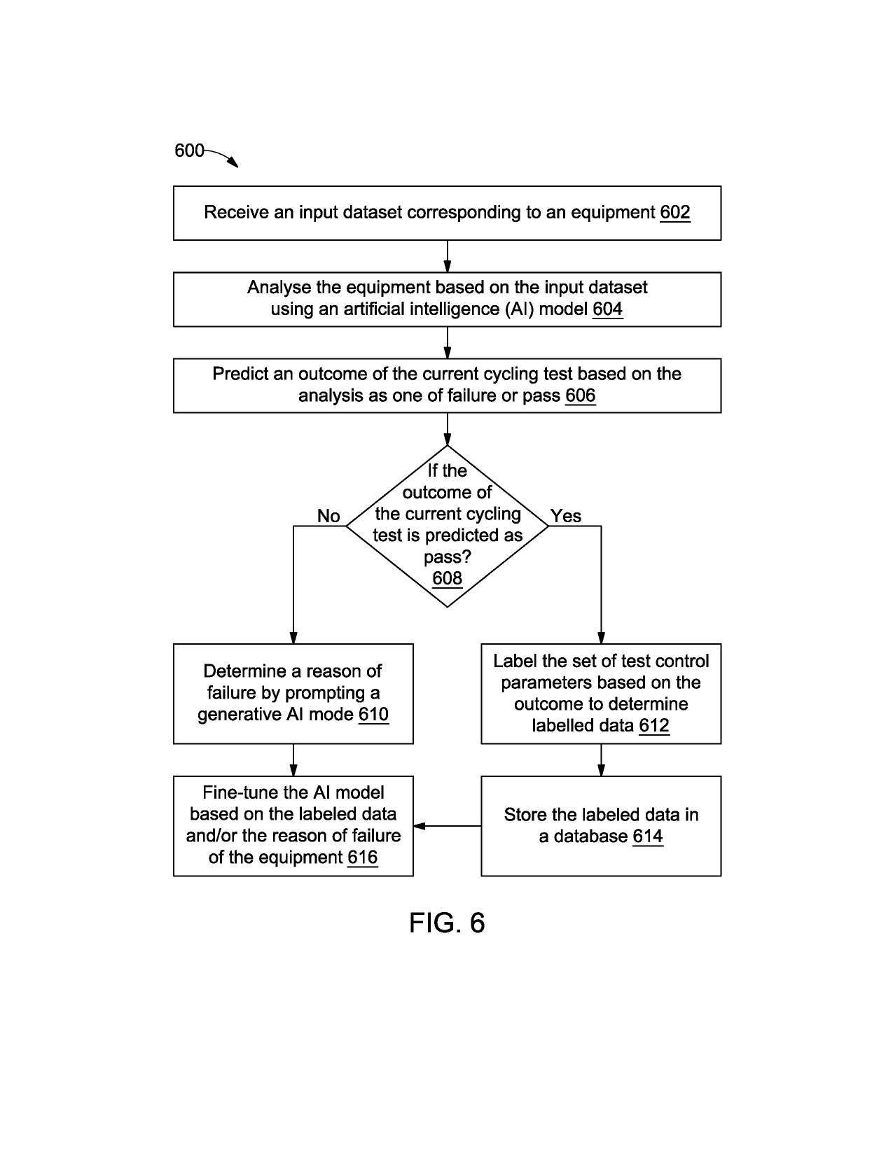

Referring now to FIG. 6, a flow diagram 600 of a methodology of analysing an equipment for current cycling test, is illustrated, in accordance with an embodiment of the present disclosure. FIG. 6 is explained in conjunction with FIGS. 1-5B. In an embodiment, the flow diagram 600 may include a plurality of steps that may be performed by various modules of the computing device 102 so as to analyse the equipment for the current cycling test.

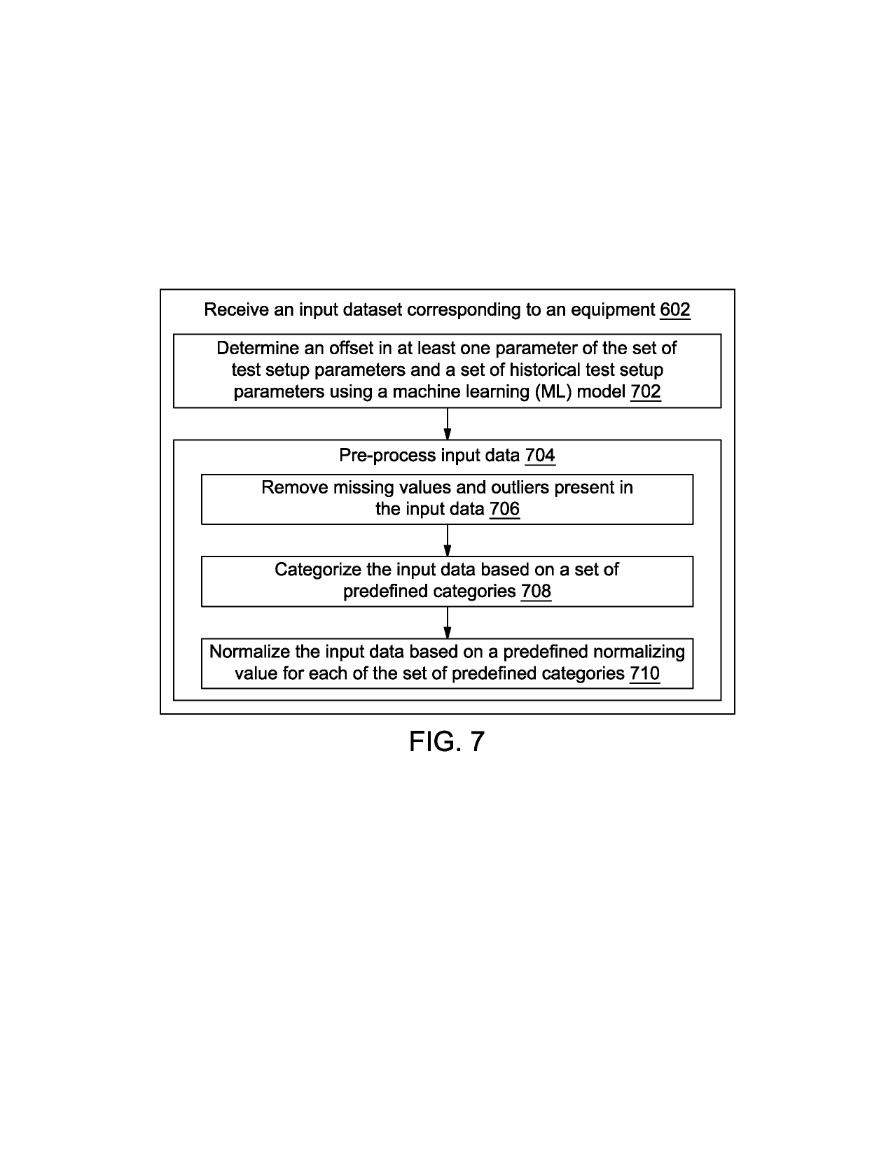

At step 602, an input dataset corresponding to the equipment may be received as an input. It should be noted that the input may be indicated or provided by a user via the I/O device 108. Examples of the equipment may include but not limited to, neutral bars, lugs, power cables, electric motors, transformers, and other electrical components. The input dataset may include a set of control parameters, specification data, historical cycling test data and a set of test setup parameters. The determination of the set of test setup parameters will be explained in greater detail below in FIG. 7. The determination of the input dataset will be explained in greater detail below in FIG. 7. In an embodiment, the historical cycling test data may include historical test data for a set of historical test setup parameters. In an embodiment, the specification data may include shape information, size information, type information, material information, and metallography parameters of the equipment. In an embodiment, the set of test control parameters may include an input current data, a cable type, a cable thickness, and voltage drop data. In an embodiment, the set of test setup parameters may include an ambient temperature.

Further at step 604, the equipment may be analysed based on the input dataset using an artificial intelligence (AI) model. In an embodiment, the analysis may be based on a validation of the specification data, the set of test control parameters and the set of test setup parameters with respect to the historical cycling test data. In an embodiment, the AI model may be trained to validate the specification data, the set of test control parameters and the set of test setup parameters based on the historical test data.

Further at step 606, an outcome of the current cycling test may be predicted based on the analysis as one of failure or pass. Further at step 608, a check is performed to determine if the outcome of the current cycling test is predicted as pass or not. Upon predicting the outcome as failure, a reason of failure is determined, at step 610, by prompting a generative AI model. The generative AI model may be prompted based on the specification data, the historical cycling test data and the set of test setup parameters.

Further, upon predicting the outcome as pass, the set of test control parameters may be labelled, at step 612, based on the outcome to determine labelled data. Further at step 614, the labelled data may be stored in the database. Further at step 616, the AI model may be fine-tuned based on the labelled data and/or the reason of failure of the equipment.

Referring now to FIG. 7, a flow diagram of a methodology of determining the input dataset corresponding to the equipment, in accordance with an embodiment of present disclosure. FIG. 7 is explained in conjunction with FIGS. 6. In an embodiment, the flow diagram may include a plurality of steps that may be performed by various modules of the computing device 102 so as to determine the input dataset corresponding to the equipment.

At step 702, to determine the set of test setup parameters, an offset in at least one parameter of a set of preliminary test setup parameters and a set of historical test setup parameters using a machine learning (ML) model. The set of test setup parameters may be forecasted based on the offset using the ML model.

Further at step 704, to determine the input dataset, input data may be pre-processed. In order to pre-process the input data, at step 706, missing values and outliers present in the input data may be removed. Further at step 708, the input data may be categorized based on a set of predefined categories. Further at step 710, the input data may be normalized based on a predefined normalizing value for each of the set of predefined categories.

Thus, the disclosed method 600 and system 100 overcome the challenges associated with conventional current cycling tests by introducing an automated, data-driven approach that enhances efficiency and reduces testing durations. The method leverages artificial intelligence (AI) to analyse historical cycling test data and dynamically adjust testing parameters, thereby minimizing the overall time required to assess equipment performance. By employing predictive analytics, the system 100 can identify potential failure points, thus enabling earlier intervention and reducing the need for prolonged current testing cycles. This not only conserves resources such as electricity, equipment wear, and manpower but also mitigates the financial burden associated with delays and repetitive testing.

As will be appreciated by those skilled in the art, the techniques described in the various embodiments discussed above are not routine, or conventional, or well-understood in the art. The techniques discussed above provide for analysing an equipment for current cycling test.

In light of the above-mentioned advantages and the technical advancements provided by the disclosed method and system, the claimed steps as discussed above are not routine, conventional, or well understood in the art, as the claimed steps enable the following solutions to the existing problems in conventional technologies. Further, the claimed steps bring an improvement in the functioning of the device itself as the claimed steps provide a technical solution to a technical problem.

The specification has described the method and system for analysing an equipment for current cycling test. The illustrated steps are set out to explain the exemplary embodiments shown, and it should be anticipated that ongoing technological development will change the manner in which particular functions are performed. These examples are presented herein for the purpose of illustration, and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, etc., of those described herein) will be apparent to persons skilled in the relevant art(s) based on the teachings contained herein. Such alternatives fall within the scope and spirit of the disclosed embodiments.

It is intended that the disclosure and examples be considered as exemplary only, with a true scope of disclosed embodiments being indicated by the following claims.

What is claimed is:

1. A method of analysing an equipment for current cycling test, the method comprising:
receiving, by a processor, an input dataset corresponding to the equipment,
wherein the input dataset comprises a set of test control parameters, specification data, historical cycling test data and a set of test setup parameters;
analysing, by the processor, the equipment based on the input dataset using an artificial intelligence (AI) model,
wherein the analysis is based on a validation of the specification data, the set of test control parameters and the set of test setup parameters with respect to the historical cycling test data, and
wherein the AI model is trained to validate the specification data, the set of test control parameters and the set of test setup parameters based on the historical test data;
predicting, by the processor, an outcome of the current cycling test based on the analysis as one of failure or pass; and
upon predicting the outcome as failure, determining, by the processor, a reason of failure by prompting a generative AI model, wherein the generative AI model is prompted based on the specification data, the historical cycling test data and the set of test setup parameters.

2. The method of claim 1, wherein the historical cycling test data comprises historical test data for a set of historical test setup parameters, wherein the specification data comprises shape information, size information, type information, material information, and metallography parameters of the equipment, wherein the set of test control parameters comprises an input current data, a cable type, a cable thickness, and voltage drop data, and wherein the set of test setup parameters comprises an ambient temperature.

3. The method of claim 1, further comprising:
determining, by the processor, an offset in at least one parameter of a set of preliminary test setup parameters and a set of historical test setup parameters using a machine learning (ML) model,
wherein the set of test setup parameters are forecasted based on the offset using the ML model.

4. The method of claim 1, wherein the input dataset is determined by:
pre-processing, by the processor, an input data by:
removing, by the processor, missing values and outliers present in the input data;
categorizing, by the processor, the input data based on a set of predefined categories; and
normalizing, by the processor, the input data based on a predefined normalizing value for each of the set of predefined categories.

5. The method of claim 1, wherein upon determining the outcome as pass:
labelling, by the processor, the set of test control parameters based on the outcome to determine labelled data; and
storing, by the processor, the labelled data in a database.

6. The method of claim 5, comprising:
fine-tuning, by the processor, the AI model based on the labelled data and/or the reason of failure of the equipment.

7. A system for analysing an equipment for current cycling test, comprising:
a processor;
a memory communicably coupled to the processor, wherein the memory stores processor-executable instructions, which, on execution, cause the processor to:
receive an input dataset corresponding to the equipment,
wherein the input dataset comprises a set of test control parameters, specification data, historical cycling test data and a set of test setup parameters;
analyse the equipment based on the input dataset using an artificial intelligence (AI) model,
wherein the analysis is based on a validation of the specification data, the set of test control parameters and the set of test setup parameters with respect to the historical cycling test data, and
wherein the AI model is trained to validate the specification data, the set of test control parameters and the set of test setup parameters based on the historical cycling test data;
predict an outcome of the current cycling test based on the analysis as one of failure or pass; and
upon prediction of the outcome as failure, determine a reason of failure by prompting a generative AI model, wherein the generative AI model is prompted based on the specification data, the historical cycling test data and the set of test setup parameters.

8. The system of claim 7, wherein the historical cycling test data comprises historical test data for a set of historical test setup parameters, wherein the specification data comprises shape information, sized information, type information, material information, and metallography parameters of the equipment, wherein the set of test control parameters comprises an input current data, a cable type, a cable thickness, and voltage drop data, and wherein the set of test setup parameters comprises an ambient temperature.

9. The system of claim 7, wherein the processor-executable instructions, which, on execution, further cause the processor to:
determine an offset in at least one parameter of a set of preliminary test setup parameters and a set of historical test setup parameters using a machine learning (ML) model,
wherein the set of test setup parameters are forecasted based on the offset using the ML model.

10. The system of claim 7, wherein to determine the input dataset, the processor-executable instructions, which, on execution, cause the processor to:
pre-process an input data by:
removing missing values and outliers present in the input data;
categorizing the input data based on a set of predefined categories; and
normalizing the input data based on a predefined normalizing value for each of the set of predefined categories.

11. The system of as claimed in claim 7, wherein upon determination of the outcome as pass, the processor-executable instructions, which, on execution, further cause the processor to:
label the set of test control parameters based on the outcome to determine labelled data; and
store the labelled data in a database.

12. The system of claim 11, wherein the processor-executable instructions, which, on execution, further cause the processor to:
fine-tune the AI model based on the labelled data and/or the reason of failure of the equipment.

13. A non-transitory computer-readable medium storing computer-executable instructions for analysing an equipment for current cycling test, the computer-executable instructions configured for:
receiving an input dataset corresponding to the equipment,
wherein the input dataset comprises a set of test control parameters, specification data, historical cycling test data and a set of test setup parameters;
analysing the equipment based on the input dataset using an artificial intelligence (AI) model,
wherein the analysis is based on a validation of the specification data, the set of test control parameters and the set of test setup parameters with respect to the historical cycling test data, and
wherein the AI model is trained to validate the specification data, the set of test control parameters and the set of test setup parameters based on the historical test data;
predicting an outcome of the current cycling test based on the analysis as one of failure or pass; and
upon predicting the outcome as failure, determining a reason of failure by prompting a generative AI model, wherein the generative AI model is prompted based on the specification data, the historical cycling test data and the set of test setup parameters.

14. The non-transitory computer-readable medium of claim 13, wherein the historical cycling test data comprises historical test data for a set of historical test setup parameters, wherein the specification data comprises shape information, size information, type information, material information, and metallography parameters of the equipment, wherein the set of test control parameters comprises an input current data, a cable type, a cable thickness, and voltage drop data, and wherein the set of test setup parameters comprises an ambient temperature.

15. The non-transitory computer-readable medium of claim 13, wherein the computer-executable instructions are further configured for:
determining an offset in at least one parameter of a set of preliminary test setup parameters and a set of historical test setup parameters using a machine learning (ML) model,
wherein the set of test setup parameters are forecasted based on the offset using the ML model.

16. The non-transitory computer-readable medium of claim 13, wherein to determine the input dataset, the computer-executable instructions are configured for:
pre-processing an input data by:
removing missing values and outliers present in the input data;
categorizing the input data based on a set of predefined categories; and
normalizing the input data based on a predefined normalizing value for each of the set of predefined categories.

17. The non-transitory computer-readable medium of claim 13, wherein upon determining the outcome as pass, the computer-executable instructions are configured for:
labelling the set of test control parameters based on the outcome to determine labelled data; and
storing the labelled data in a database.

18. The non-transitory computer-readable medium of claim 17, wherein the computer-executable instructions are further configured for:
fine-tuning the AI model based on the labelled data and/or the reason of failure of the equipment.
